(19) United States
(12) Patent Application Publication
(10) Pub. No.: US 2018/0102553 A1
(43) Pub. Date: Apr. 12, 2018

(54) PORTABLE SOLAR ENERGY STORAGE SYSTEM USING IONIC POLYMER METAL COMPOSITE ENHANCED WATER ELECTROLYSIS

(71) Applicant: Wichita State University, Wichita, KS (US)

(72) Inventor: Zheng Chen, Andover, KS (US)

(21) Appl. No.: 15/726,748

(22) Filed: Oct. 6, 2017

Related U.S. Application Data
(60) Provisional application No. 62/405,550, filed on Oct. 7, 2016.

(51) Int. Cl. H01M 8/0239; B01D 71/32; H01M 8/1086; H01M 8/0232

(52) U.S. Cl. CPC H01M 8/0239; B01D 71/32; H01L 31/02008; H01M 8/0232; H01M 2250/30; H01M 8/1086

(57) ABSTRACT

Provided herein are fabricated ionic polymer-composite metal membranes and energy storage systems comprising the same. The energy storage systems are particularly suitable for solar powered, portable hydrogen fuel cells. The systems are capable of converting renewable energy, such as solar radiation, into electrical energy, which is used to perform water electrolysis to create and store hydrogen fuel. The system can then act as a fuel cell, converting the hydrogen fuel into electrical energy that can be used, for example, to charge a mobile device. The membranes are advantageously smaller and more efficient than prior art electrolyzer membranes. This is due to an advanced fabrication technique also described herein.

### CROSS-REFERENCE TO RELATED APPLICATIONS

The present application claims the priority benefit of U.S. Provisional Patent Application Ser. No. 62/405,550, filed Oct. 7, 2016, entitled PORTABLE SOLAR ENERGY STORAGE SYSTEM USING IONIC POLYMER METAL COMPOSITE ENHANCED WATER ELECTROLYSIS, incorporated by reference in its entirety herein.

### BACKGROUND OF THE INVENTION

### Field of the Invention

The present invention is generally directed to fabricated ionic polymer-composite metal membranes and their use in hydrogen fuel cells. The membranes and hydrogen fuel cells are particularly suitable for use in solar-powered, portable mobile device chargers.

### Description of Related Art

The call for renewable energy is increasing. As dependence on traditional sources of energy such as coal and natural gas continue to decline, there will be an increased need for renewable energy. A large portion of pollutants come from currently used energy sources, such as coal. This has led to an increased effort to provide renewable energy on a large scale. The European Union (EU) has a large dependency on oil imports from foreign countries. In 2014, more than half of the EU's energy consumption came from imported sources, and about 25% came from renewable energy sources. As hydrogen fuel becomes more viable, EU countries may be more likely to adopt this alternative form of energy, as the only resource needed to produce hydrogen fuel is water.

In 2012, only about 10% of energy consumed in the United States was from renewable energy sources. Historically, the United States government has provided subsidies for many different forms of energy production, however the largest portion of these subsidies traditionally went to oil and gas companies. This trend has changed in recent years, with about 45%, or $7.3 billion, of all energy subsidies provided by the United States government going to renewable energy, while fossil fuel energy received $3.2 billion in subsidies. A 2009 study by the Environmental Law Institute that studied U.S. energy subsidies from 2002-2008 estimated that subsidies to fossil fuel sources totaled about $72 billion during that time, while subsidies to renewable energy sources totaled $29 billion. As progression continues, there will be more opportunities for renewable energy to enter the mainstream and become the primary source of energy in the United States.

Energy subsidies are a large economic factor in increasing renewable energy production. As subsidies continue to increase, renewable energy will grow more quickly than it would if left unsubsidized. Electric power consumption is expected to rise, increasing the need for energy. The price of natural gas directly affects the demand for renewable energy. As the price of natural gas goes up, the demand for renewable energy goes up. The growth of solar energy has rapidly grown in the past five years, partially because of the declining price of solar panels. This trend is expected to continue, as revenue from solar energy is expected to grow.

Renewable energy, in general, is a rapidly growing industry, as more and more countries aim to reduce and eventually eliminate their need for oil and gas. The United States government as well as other countries have been giving credits, grants, and tax exemptions to those working on renewable energy research. Over the next five years, solar energy revenue is expected to increase 6.5% annually up to $4.4 billion in revenue (IBIS World). In the next five years, it is expected that photovoltonic power will achieve “grid parity” meaning that the cost of solar energy will be the same or less than the retail rate of grid power. This means that the industry is becoming more viable, and will likely reduce its dependence on government assistance. Another challenge will be the global rise in energy demand. The U.S. demand for energy is expected to increase 14-28% from 2005 through 2030. There is currently not enough supply to meet this demand, so solutions must be created. Renewable energy is expected to provide a much bigger portion of total energy consumed as well.

Although there is heavy regulation in the energy industry, a large amount of regulation is aimed at reducing the amount of emissions and increasing the use of renewable energy technologies. These regulations directly benefit the solar energy industry. More than 30 U.S. states and territories have renewable energy standards that require electric providers to gradually increase the amount of renewable, typically non□hydroelectric energy sources to their power supplies.

Mobile electronics, such as digital cameras, smart phones, and mobile computers have made a great impact on our daily lives, and as a result, sustainable and portable energy storage systems are in great need to provide continuous power for these mobile electronics. To obtain a sustainable energy source, portable renewable energy harvesters, such as solar cells, micro wind turbines, and kinetic energy harvesters have been developed to convert renewable energy into electricity for mobile electronics, mobile robots, and wireless sensing notes. However, since the power output of a renewable energy harvester does not match the electricity usage of mobile electronics most of the time, an energy efficient and portable renewable energy storage device is needed to balance this mismatch.

To solve the issue, people have turned to water electrolysis that can convert electricity into hydrogen fuel. The traditional water electrolysis generator utilizes two platinum or titanium electrodes placed in an electrolyte solution, such as sulfuric acid (H₂SO₄) or potassium hydroxide (KOH), to collect oxygen gas and hydrogen gas from the anode and cathode, respectively. Since the traditional water electrolysis relies on toxic chemicals, the overall system becomes bulky, heavy, and environmentally unfriendly. To build a simple and compact solar energy storage system, many researchers have applied photocatalysis to directly convert solar energy into hydrogen fuel. However, the energy-conversion efficiency of photocatalytic hydrogen production is still very low.

Recent advances in proton exchange membrane (PEM) have made hydrogen production more reliable and environmentally friendly. The PEM acts as a solid electrolyzer in water electrolysis, which provides a non-toxic and lightweight medium for hydrogen production. However, there are no products that use strictly solar energy to create hydrogen fuel in a portable device. Some devices either require the consumer to replace the hydrogen cartridges, or purchase a separate electrolysis machine that must be plugged in for power. The quality of other solar charging devices is questionable, as the solar panels often do not produce enough energy on their own to fully charge a mobile device quickly, and require a battery that can be charged through an electrical outlet.

As the cost of solar energy continues to decline, more technological advancements will be made to increase the efficiency and make solar energy more cost effective. A large obstacle in providing consistent solar energy is the inefficiency of current battery technology. Solar panels depend on the energy from the sun, so solar energy systems must contain an energy storage system.

What is needed is an efficient, portable system to charge mobile devices in situations when no electricity is available. These situations would often involve the need to charge mobile devices in remote locations. As humans increasingly rely on technology, energy consumption and demand will continue to rise, and consumers will demand the freedom to charge any mobile device at any time without the use of an outside power source.

### SUMMARY OF THE INVENTION

Embodiments described herein are generally directed to energy storage systems that are particularly suitable for solar powered, portable mobile device chargers that can be roughly the size of a cell phone. The systems are capable of converting renewable energy, such as solar radiation, into electrical energy, which is used to perform water electrolysis to create and store hydrogen fuel. The system can then act as a fuel cell, converting the hydrogen fuel into electrical energy that is used to charge a mobile device. When the system is producing more energy than the output is consuming, it will create hydrogen fuel, and when the system is consuming more energy than it is producing, it will act as a fuel cell and use the hydrogen fuel to create electrical energy. The system is powered by an electrolyzer comprising an ionic polymer metal composite membrane, which has heretofore never been used for this purpose.

In one embodiment, there is provided an ionic polymer metal composite membrane adapted for use as an electrolyzer in a hydrogen fuel cell. The membrane has an average thickness of less than about 300 μm and comprises an ionic polymer film having at least one major surface in direct contact with a noble metal electrode. An energy storage system comprising an electrolyzer formed from the membrane is also provided.

In another embodiment, there is provided a method of producing an electrolyzer membrane from an ionic polymer film. The method comprises at least one of the following steps: (i) spin-coating an ionic polymer solution onto a substrate to form the ionic polymer film; or (ii) etching the ionic polymer film. The method further comprises contacting at least one major surface of the ionic polymer film with a noble metal electrode layer to form the electrolyzer membrane.

In yet another embodiment, there is provided a method of storing hydrogen fuel in an energy storage system. The method comprises supplying a source of electricity and a source of water to the fuel cell, and producing hydrogen gas. The fuel cell comprises an ionic polymer metal composite electrolyzer membrane.

### BRIEF DESCRIPTION OF THE DRAWINGS

FIG. 1 is a schematic diagram of an energy storage system according to one embodiment of the present invention;

FIG. 2 is a graph showing hydrogen generation rate versus input power using an ionic polymer metal composite membrane electrolyzer;

FIG. 3 is a graph showing energy conversion efficiency versus input voltage using an ionic polymer metal composite membrane electrolyzer; and

FIG. 4 is a graph showing hydrogen generation rate using solar power as the electricity source for an ionic polymer metal composite membrane electrolyzer.

### DETAILED DESCRIPTION OF THE PREFERRED EMBODIMENTS

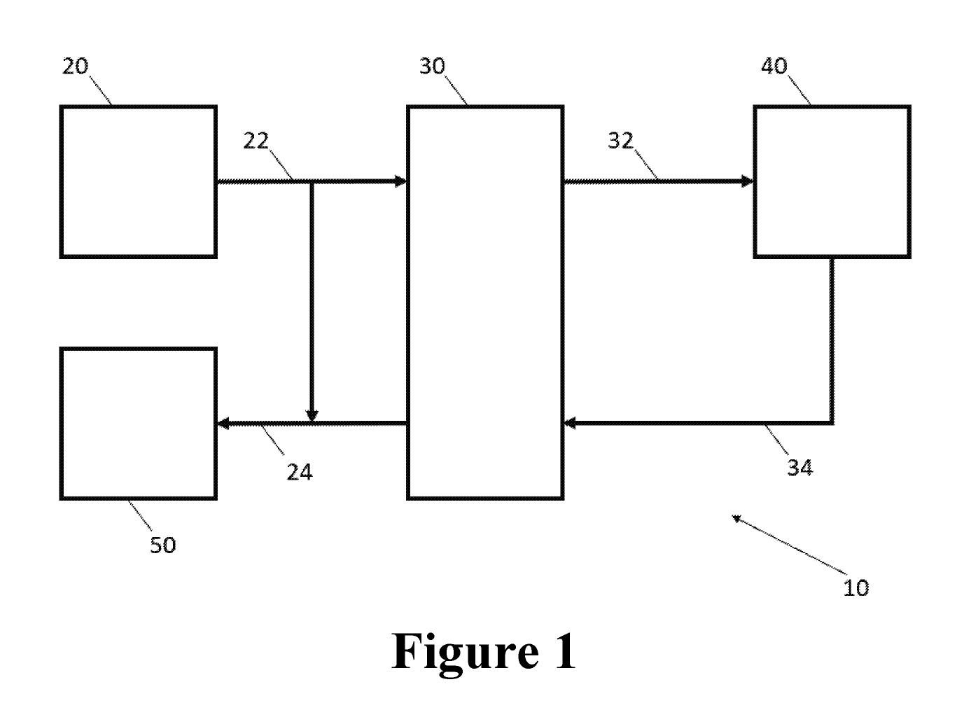

Embodiments described herein are directed to ionic polymer-composite metal (IPMC) membranes that are fabricated to be smaller and more efficient than prior art fuel cell electrolyzer membranes. The reduced size and increased efficiency makes the membranes particularly useful for portable energy storage applications. An exemplary energy storage system 10 enabled by an IPMC membrane electrolyzer is shown in FIG. 1. As shown in FIG. 1, system 10 generally comprises electricity source 20, electrolyzer 30, and reservoirs 40. Electricity source 20 may comprise any of a variety of known renewable energy harvesters, such as solar cells, micro wind turbines, kinetic energy harvesters, and the like. In a particularly preferred embodiment, electricity source 20 comprises one or more solar cells. Electricity source 20 is configured to supply electricity to system 10 via electricity input 22. The electricity via input 22 may be distributed directly to output 24, for example when there is immediate energy demand by consumer 50, and/or the electricity via input 22 may be directed to electrolyzer 30 to supply the electricity for water electrolysis via an IPMC membrane. When electricity via input 22 is being supplied, electrolyzer 30 generates hydrogen and oxygen gasses that are sent to storage reservoirs 40 via gas output 32. Advantageously, smaller power inputs may be used to produce hydrogen from electrolysis using the IPMC membranes described herein. For example, DC voltages of less than about 2V (and as low as about 1.6V) may be supplied by electricity source 20 to electrolyzer 30 to induce electrolysis in a water source and produce a large amount of hydrogen and oxygen gases. Greater voltages may also be supplied, which can increase hydrogen gas production. When there is sufficient energy demand, hydrogen and oxygen gasses are sent from reservoirs 40 to electrolyzer 30 via gas input 34 to generate electricity by fuel cell electrolysis, which is distributed to consumer 50 via output 24.

Advantageously, the same IPMC membrane can be used for both water electrolysis (electricity to hydrogen) production and fuel cell electrolysis (hydrogen to electricity). The IPMC membrane can be positioned within the water source (not shown) to separate reservoirs 40 into distinct oxygen and hydrogen gas chambers. The IPMC membrane therefore provides a lightweight, compact, and energy-efficient electrolyzer for both water electrolysis and fuel cell electrolysis to balance the mismatch between the peak of energy harvesting (e.g., daytime sun for solar energy) and the peak of energy consumption (e.g., evenings). The IPMC membrane is advantageous over prior art electrolyzer membranes for energy storage systems due to the improved energy efficiency and reduced weight and space.

IPMC membranes in accordance with embodiments of the present invention are adapted for use as solid, ion exchange membranes for hydrogen production by water electrolysis. The membranes generally comprise an ionic polymer film having opposed major surfaces. An electrode layer (or layers) is formed in a face-to-face relationship immediately adjacent (i.e., directly on) at least one major surface of the film. The membranes can be a variety of shapes and sizes, depending on the particular application. Advantageously, however, IPMC membranes in accordance with embodiments of the present invention can be made much thinner than prior art fuel cell membranes. For example, in certain embodiments, the IPMC membrane has an average thickness of less than about 300 μm, preferably less than about 200 μm, more preferably less than about 100 μm, and even more preferably less than 75 μm.

The ionic polymer film generally comprises an electroactive polymer. In certain embodiments, the ionic polymer film comprises an electroactive polymer selected from the group consisting of fluoropolymer-copolymers, fluorinated carboxylic polymers, combinations thereof, and derivatives thereof. In a particularly preferred embodiment, the ionic polymer film comprises a sulfonated tetrafluoroethylene based fluoropolymer-copolymer, such as NAFION® (Dupont). In one or more embodiments, the ionic polymer film further comprises a plurality of carbon nanofibers dispersed therein. Carbon nanofibers generally comprise cylindric nanostructures with graphene layers arranged as stacked cones, cups, plates, or nanotubes. The ionic polymer film is advantageously thinner than traditional solid electrolytes, thereby providing a shorter distance for ion transportation across the film. It has been discovered that this shortens the time for cations to reach the polymer-metal interface where water electrolysis occurs in a fuel cell, thereby allowing for more efficient hydrogen production. In certain embodiments, the ionic polymer film has an average thickness of less than about 200 μm, preferably less than about 100 μm, more preferably less than about 50 μm, and even more preferably from about 5 to about 50 μm.

The electrodes comprise an anode (positively charged electrode) and cathode (negatively charged electrode) in contact with at least one surface of the ionic polymer film. The electrodes generally comprise one or more electrically conductive metals. In preferred embodiments, the electrodes comprise one or more noble metals, which are resistant to corrosion and oxidation, including alloys comprising a noble metal. In certain preferred embodiments, the electrodes comprise a noble metal selected from the group consisting of platinum (Pt), gold (Au), ruthenium (Ru), rhodium (Rh), palladium (Pd), silver (Ag), osmium (Os), iridium (Ir), alloys thereof, and combinations thereof. Other corrosion-resistant metals and alloys may also be used. The electrodes are configured to allow positive ion transportation through the film when an electric potential difference (or voltage) is applied across the electrodes. In certain embodiments, the electrodes are in contact with each of the opposing sides of the film, thereby allowing ion transport from one side of the film to the other (across the film thickness). However, in other embodiments, both electrodes may be in contact with a single side of the ionic polymer film. The electrodes may be integrally formed on the surface of the ionic polymer film, or they may be provided as separate components that are positioned to contact the film surface (e.g., plates or clamps). In certain embodiments, one or both of the electrodes may comprise a thin layer of metal integrally-formed directly on one or both major surfaces of the polymer film. For example, in certain embodiments, an electrode layer is formed on the surface of the ionic polymer film by electroless plating.

An advanced fabrication method can be used in accordance with embodiments of the present invention to fabricate IPMC membranes that exhibit advantages over prior art membranes. Specifically, one or more of the following three processes may be used to produce an IPMC membrane: (1) spin-coating the ionic polymer film to produce a thinner film compared to traditional membranes, thereby shortening the ion transportation distance; (2) treating (e.g., by etching) one or both surfaces of the ionic polymer film to roughen the surface(s) and create micro-hair-like structures at the polymer-metal interface, thereby increasing the surface area for the connection at this interface; and (3) replacing existing positive ions with small cations, such as lithium, using an ion exchange process.

An exemplary advanced fabrication method, in accordance with one embodiment of the present invention, is described below. However, it should be understood that other techniques and variations of this method may also be used in accordance with other embodiments of the present invention.

Spin-Coating.

Ion transportation distance in an ionic polymer film delays the cations in reaching the polymer-metal interface where water electrolysis occurs. It has been discovered that the thickness of the ionic polymer film can be reduced (compared to prior art films) by spinning an ionic polymer solution on a silicon wafer to create a micro-thin layer of ionic polymer film. Carbon nanofibers may be added to the solution. The first step in the spin-coating process is preparing the silicon substrate. The substrate may be prepared by depositing an aluminum layer on the backside of a highly boron-doped silicon wafer using physical vapor deposition (PVD), spin coating, or sputtering. A photoresist mask may then be developed using lithography techniques, and the aluminum etched in the backside open area, so that KOH or XeF₂ can subsequently etch through the silicon wafer in a later step. A thin layer of conductive glue can then be coated on the front side of the silicon wafer. The ionic polymer solution is then mixed with carbon nanofibers and applied to the front side of the spinning wafer. The solution is then cured at 100° C. to obtain a micro-thin layer of ionic polymer film. The silicon can then be etched from the backside using KOH or XeF₂ etching, and the conductive glue on the backside of the polymer film removed using oxygen plasma etching.

Surface Treatment.

Most water electrolysis occurs at the polymer-metal interface of an IPMC membrane. The larger the interface area, the more hydrogen gas produced. Thus, one or both of the surfaces of the polymer film may be treated to roughen the surface(s), thereby increasing the interface area. The surface(s) may be roughened using a variety of methods known in the art, for example blowing glass beads on the surface or etching. In preferred embodiments, the surface(s) are etched using a reactive ion etching (ME) process. RIE etching is a type of dry etching technique that uses chemically reactive plasma to remove material from a surface. The plasma is generated under low pressure (vacuum) by an electromagnetic field, and high-energy ions from the plasma attack the surface and react with it to remove the material.

The electrode layers can be formed on the ionic polymer film after the spin-coating process and/or surface treatment process described above. At this point, the noble metal electrode can be deposited on the film to provide the polymer-metal interface. For example, a micro-thin layer of platinum metal can be grown on the ionic film surface using electroless plating.

Ion-Exchange Process.

Large cations such as sodium and calcium cannot be transported through the membrane quickly, which causes energy lost during the transportation due to the ion diffusion resistance. Thus, these traditional large cations are exchanged for smaller cations, such as lithium ions, so that the small cations can be transported faster with less energy lost. An ion-exchange process can thus be used to replace the existing cations in the IPMC membrane with smaller cations. As a result, the ion-exchange process improves the energy-conversion efficiency of the IPMC-enabled water electrolysis. In certain embodiments, the ion-exchange process comprises boiling the IPMC membrane in a lithium-ion-concentrated solution to exchange the existing cations with lithium cations.

The fabricated IPMC membranes and energy storage systems in accordance with embodiments of the present invention are particularly suited for small, portable device applications. In a particularly preferred embodiment, the IPMC membrane is used in a lightweight, portable, solar energy storage system for powering mobile electronics. The system creates hydrogen fuel through water electrolysis, when the system is consuming less energy than it is producing, and can act as a fuel cell when power consumption is greater than the rate of energy being produced by the solar panel. The system can advantageously use a single IPMC membrane for both water electrolysis and fuel cell electrolysis. The system comprises a solar cell, an IPMC, a water tank, an oxygen tank, and a hydrogen tank. The system may further comprise additional components as needed or desired, depending on the particular application. For example, a lithium ion battery may also be included in the system as a backup power supply.

Since the IPMC can be used as an electrolyzer for both water electrolysis and fuel cell electrolysis, a control system may be included in order to create a balance between solar energy production and power consumption. To increase the power output of the energy system, a multi-stacked solar energy storage device comprising a multi-layer IPMC electrolyzer can be used. Particularly, using the advanced fabrication process described above, a micro-thin IPMC electrolyzer can be fabricated and inserted into the multi-stacked device. The electrolyzer can then be soaked with pure water and sealed in an enclosed chamber. The gap between the electrolyzer will work as a gas chamber for either oxygen gas or hydrogen gas. Such a device is more lightweight, compact, and energy-conversion efficient compared to prior art devices. As indicated above, the energy storage system may be a variety of shapes and sizes, depending on the specific application and energy storage capacity desired. In certain embodiments, however, the system is provided as a relatively small, portable device having a volume of about 10 cc to about 1500 cc, preferably about 50 cc to about 1000 cc, and more preferably about 100 cc to about 500 cc.

Embodiments of described herein have a number of advantageous features over traditional membranes and energy storage devices. For example, embodiments of the present invention utilize a combination of solar energy and hydrogen fuel to provide an efficient fuel cell using an IPMC membrane in the electrolyzer. Thus, the system can be used as a lightweight, portable, solar, hydrogen fuel generator/fuel cell. This system is an effective and efficient way to store electricity, with certain embodiments having an energy conversion efficiency greater than about 80%. The IPMC membrane utilized in accordance with the present invention preferably employs lithium ions for the electrolyte ion transfer, compared to prior art PEM membranes that use only hydrogen ions, thereby allowing greater energy production while maintaining faster ion transfer. The system also has a higher energy output than prior art portable renewable energy systems. The systems and devices in accordance with the present invention overcome the inefficiencies of solar panels by using the solar energy to create hydrogen fuel that is stored in the device, and the use of fabricated IPMC membranes as electrolyzers also increases the efficiency over prior art systems. The use of the IPMC membrane electrolyzer allows for a larger volume of energy to be stored in a shorter amount of time compared to PEM membranes.

Additional advantages of the various embodiments of the invention will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments, but is not necessarily included. Thus, the present invention encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments of the invention. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth efficacy studies of membranes and systems in accordance with embodiments of the present invention. It is to be understood, however, that these examples are provided by way of illustration and nothing therein should be taken as a limitation upon the overall scope of the invention.

### Example I

In this experiment, the energy-conversion efficiency of an IPMC membrane electrolyzer was measured. A testbed was developed for measuring the energy-conversion efficiency. A controllable DC power supply was used to apply DC voltage to the IPMC. Both current and voltage were measured, and the electrical power input was then calculated. Two graduated tubes were used to collect and measure the generated hydrogen and oxygen gases, respectively. The test was performed with a standard 5 cm-by-5 cm and 280 μm thick IPMC clamped between two gold electrodes. The IPMC film was reinforced by TEFLON® fibers to reduce its actuation effect. Two graduated tubes were used to collect the oxygen and hydrogen gases in 5 minutes, and then the gas volumes were measured. The hydrogen gas generation rate was calculated. The energy-conversion efficiency was calculated based on the input electrical energy and the output hydrogen fuel energy. The energy-conversion efficiency can be calculated by

$$E = \frac{V ρα \text{/} m}{UI Δ t} ,$$

where Δt is the duration time (second), U is the applied DC voltage (volt), I is the current (amp), V is the measured volume of hydrogen gas (cc), ρ is the density of hydrogen (g/cc), m is the molar mass of hydrogen (g/mol), α is the higher heat value (HHV) of hydrogen (285.8 Joul/mol).

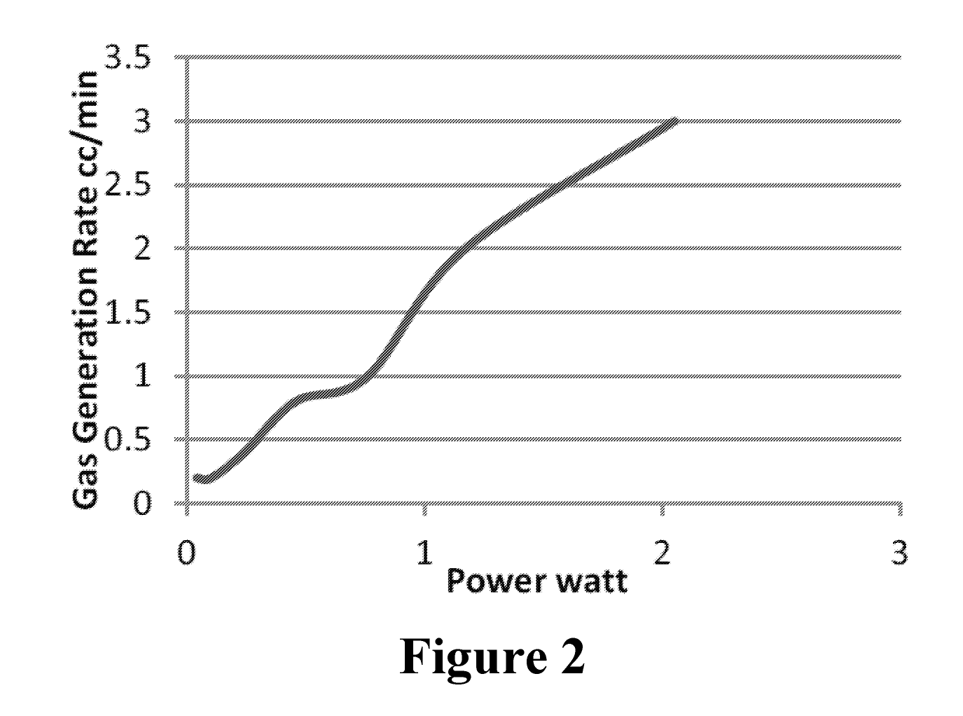

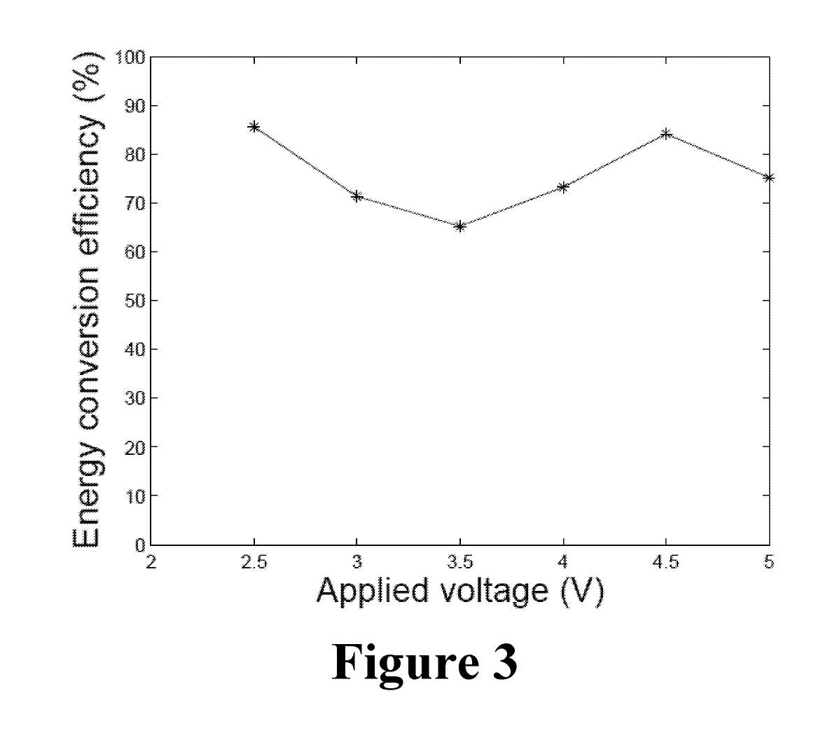

FIG. 2 shows the H2 gas generation rate versus input power, and FIG. 3 shows the energy-conversion efficiency versus input voltage. As can be seen, the efficiency can reach up to 80% with the standard IPMC, which is close to the reported PEM voltage efficiency HHV (67%-82%).

### Example II

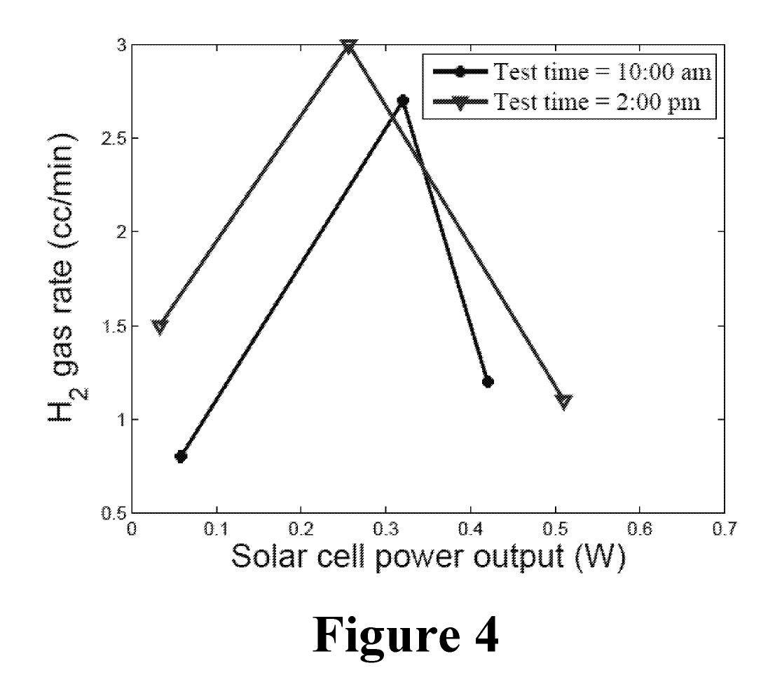

A solar energy storage system in accordance with one embodiment of the present invention, comprising IPMC-enabled water electrolysis, was tested. Two solar panels were connected in parallel to convert solar energy to electricity. A standard IPMC electrolyzer was prepared similar to Example I and was used to generate hydrogen gas via water electrolysis. Two hydrogen generation tests using solar energy as the power input were conducted in Wichita, Kans. at 10:00 am and 2:00 pm, respectively. The temperatures were 85° F. and 97° F., respectively. FIG. 4 shows that the hydrogen gas generation rate can reach up to 3 cc/min under a standard atmosphere pressure. The device generated more hydrogen gas at 2:00 pm than at 10:00 am, likely due to the solar energy density and temperature variations during that day.

1. An ionic polymer metal composite membrane adapted for use as an electrolyzer in a hydrogen fuel cell, the membrane having an average thickness of less than about 300 μm and comprising an ionic polymer film having at least one surface in direct contact with a noble metal electrode.

2. The membrane of claim 1, wherein the ionic polymer film comprises an electroactive polymer selected from the group consisting of fluoropolymer-copolymers, fluorinated carboxylic polymers, combinations thereof, and derivatives thereof.

3. The membrane of claim 1, further comprising lithium ions deposited thereon.

4. The membrane of claim 1, wherein the ionic polymer film comprises carbon nanofibers dispersed therein.

5. The membrane of claim 1, wherein the noble metal electrode layer comprises a noble metal selected from the group consisting of platinum, gold, ruthenium, rhodium, palladium, silver, osmium, iridium, alloys thereof, and combinations thereof.

6. An energy storage system comprising an electrolyzer formed from the membrane of claim 1.

7. The energy storage system of claim 6, further comprising one or more solar cells integrally formed thereon and adapted to provide a source of electricity to the electrolyzer.

8. The energy storage system of claim 6, further comprising a water source contacting the electrolyzer and adapted to form hydrogen and oxygen gasses when a source of electricity is provided to the electrolyzer.

9. The energy storage system of claim 6, the system being a portable device having a volume of about 10 cc to about 1500 cc.

10. A method of producing an electrolyzer membrane from an ionic polymer film comprising:
(i) spin-coating an ionic polymer solution onto a substrate to form the ionic polymer film; or
(ii) etching the ionic polymer film, and
contacting at least one major surface of the ionic polymer film with a noble metal electrode layer to form the electrolyzer membrane.

11. The method of claim 10, further comprising applying a lithium-ion solution to the electrolyzer membrane, thereby replacing pre-existing cations with lithium ions in the electrolyzer membrane.

12. The method of claim 10, wherein the contacting comprises integrally forming the electrode layer on the at least one major surface by electroless plating.

13. The method of claim 10, wherein the ionic polymer solution comprises carbon nanofibers dispersed therein.

14. The method of claim 10, wherein the etching comprises reactive-ion etching at least one surface of the polymer film.

15. The method of claim 10, wherein the etching reduces the average thickness of the ionic polymer film to less than about 200 μm.

16. A method of storing hydrogen fuel in an energy storage system, the method comprising:
supplying a source of electricity and a source of water to the fuel cell, the fuel cell comprising an ionic polymer metal composite electrolyzer membrane; and
producing hydrogen gas.

17. The method of claim 16, further comprising contacting the hydrogen gas with the ionic polymer metal composite electrolyzer membrane to produce electricity.

18. The method of claim 16, wherein the source of electricity comprises a renewable energy source.

19. The method of claim 16, wherein the renewable energy source comprises one or more solar cells.

20. The method of claim 16, wherein the source of electricity provides a DC voltage of less than about 2V.
